(19) United States
(12) Patent Application Publication
(10) Pub. No.: US 2010/0284435 A1
(43) Pub. Date: Nov. 11, 2010

(54) Red-Shifted Optical Feedback Laser

(76) Inventors: Martin Achtenhagen, Plano, TX (US); Linglin Jiang, Richardson, TX (US)

Correspondence Address: SLATER & MATSIL, L.L.P., 17950 PRESTON RD, SUITE 1000, DALLAS, TX, 75252-5793, US

(21) Appl. No.: 12/180,294

(22) Filed: Jul. 25, 2008

(51) Int. Cl. H01S 5/12

(52) U.S. Cl. 372/50.1

(57) ABSTRACT

A semiconductor laser is provided, and a method of producing 600-1100 laser light, and a method of making a semiconductor laser is provided. The semiconductor laser includes a quantum well layer with a spectral profile of peak wavelength λ_{g}, a laser gain region, a window region and an optical feedback region. The laser gain region is configured to accept a current injected into the quantum well layer. The window region includes a light emitting facet, wherein the window region is not configured to receive current-injection into the quantum well layer. The optical feedback region has a spectral profile of peak wavelength λ_{of}, and λ_{of}>λ_{g}.

### TECHNICAL FIELD

The present invention relates generally to a semiconductor laser, and a method of manufacture thereof, and more particularly to a high-powered laser light in the 600-1100 nm range.

### BACKGROUND

A laser is an optical source that emits photons in a coherent beam. Laser light is typically a single wavelength or color, and emitted in a narrow beam. Laser action is explained by the theories of quantum mechanics and thermodynamics. Many materials have been found to have the required characteristics to form the laser gain medium needed to power a laser, and these have led to the invention of many types of lasers with different characteristics suitable for different applications.

A semiconductor laser is a laser in which the active medium is a semiconductor. A common type of semiconductor laser is formed from a p-n junction, a region where p-type and n-type semiconductors meet, and is powered by an injected electrical current. As in other lasers, the gain region of the semiconductor laser is surrounded by an optical cavity. An optical cavity is an arrangement of mirrors or reflectors that form a standing wave resonator for light waves.

Catastrophic optical damage (COD) is a failure mode of high-power semiconductor lasers. It may occur when the semiconductor junction is overloaded by exceeding its power density and absorbs too much of the provided energy, leading to melting and recrystallization of the semiconductor material at the affected area of the laser. The affected area may be at a facet. Facets may contain a large number of lattice defects due to cleaving or etching of the facet surface. The lattice defects may negatively affect laser performance by absorbing too much of the injected energy becoming hot and melting or cracking. If the affected area is sufficiently large, it may be observable under optical microscope as darkening of the laser facet, and/or as cracks and grooves.

Presently, the amount of current injected into an infra red laser may be limited by the COD phenomena at the output facet, thereby limiting the maximum power the laser can produce. The facet may be damaged due to heat generated by the non-radiative carrier recombination. As current is injected into the gain region, the temperature increases, and the band gap shrinks, which increases the absorption coefficient and increases the current density at the facet. These effects may cause further non-radiative recombination and more heat, and an even further increase the facet temperature beyond the facet melting point and thus, damage the laser permanently. The COD problem may have a critical dominant effect in a short wavelength range, such as 600-1100 nm range. To achieve a high output power, such as 10 W or greater, COD issues need to be minimized for lasers in the infrared range.

Further, prior art semiconductor lasers may have an undesirable bi-stable turn on. As the current is increased in a prior art semiconductor laser, the laser “snaps on,” meaning that the injected threshold current is increased compared to regular threshold current, and the power jumps to certain power level.

### SUMMARY OF THE INVENTION

These and other problems are generally solved or circumvented, and technical advantages are generally achieved by forming a semiconductor laser device that red-shifts the optical feedback region peak wavelength with respect to the gain peak wavelength and limits current injection into the facet region to provide for a transparent facet region at the operational wavelength range of the semiconductor laser.

In accordance with an illustrative embodiment of the present invention, a semiconductor laser is provided. The semiconductor laser includes a quantum well layer with a peak wavelength λ_{g}, a laser gain region, a window region and an optical feedback region. The laser gain region is configured to accept a current injected into the quantum well layer. The window region includes a light emitting facet. The window region is passive. The optical feedback region has a Bragg wavelength λ_{B}, and λ_{B}>λ_{g}.

An advantage of an illustrative embodiment is providing a high-powered infrared laser with minimum or no COD failures. A further advantage of an illustrative embodiment includes providing a linearly controllable infrared laser.

Yet another advantage is providing a window/facet region transparent to the emitted light, and therefore less susceptible to failure.

The foregoing has outlined rather broadly the features and technical advantages of an illustrative embodiment in order that the detailed description of the invention that follows may be better understood. Additional features and advantages of an illustrative embodiment will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the illustrative embodiments as set forth in the appended claims.

### BRIEF DESCRIPTION OF THE DRAWINGS

For a more complete understanding of the illustrative embodiments, and the advantages thereof, reference is now made to the following descriptions taken in conjunction with the accompanying drawings, in which:

FIG. 1 shows a block diagram of a laser in accordance with an illustrative embodiment;

FIG. 2 illustrates exemplary layers of a semiconductor laser as shown on a red-shifted optical feedback DBR laser;

FIG. 3 is a graph of gain/loss (/cm) versus energy (eV) for a gain region of a semiconductor laser;

FIG. 4 shows a graph of gain/loss (/cm) versus energy (eV) for a passive region of a semiconductor laser;

FIG. 5 is a graph of reflectivity (%) versus wavelength (λ) for an optical feedback region of a semiconductor laser;

FIG. 6 shows a composite graph illustrating the function of a prior art laser;

FIG. 7 shows a power (P) versus current (I) graph illustrating the bi-stable control of a prior art laser;

FIG. 8 shows a composite graph illustrating the function of a red-shifted optical feedback laser in accordance with an illustrative embodiment;

FIG. 9 shows a power (P) versus current (I) graph illustrating a linear control of a red-shifted optical feedback laser in accordance with an illustrative embodiment; and

FIGS. 10A-10C are cross-sectional views of three embodiments of semiconductor lasers with red-shifted optical feedback regions.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that an illustrative embodiment provides many applicable inventive concepts that can be embodied in a wide variety of specific contexts. The specific embodiments discussed are merely illustrative of specific ways to make and use the invention, and do not limit the scope of the invention.

The present invention will be described with respect to illustrative embodiments in a specific context, namely a laser diode producing light in the infrared range of 600-1100 nm at an increased power of, for example, 5 W or greater. The invention may also be applied, however, to other semiconductor laser diodes producing other wavelengths and powers.

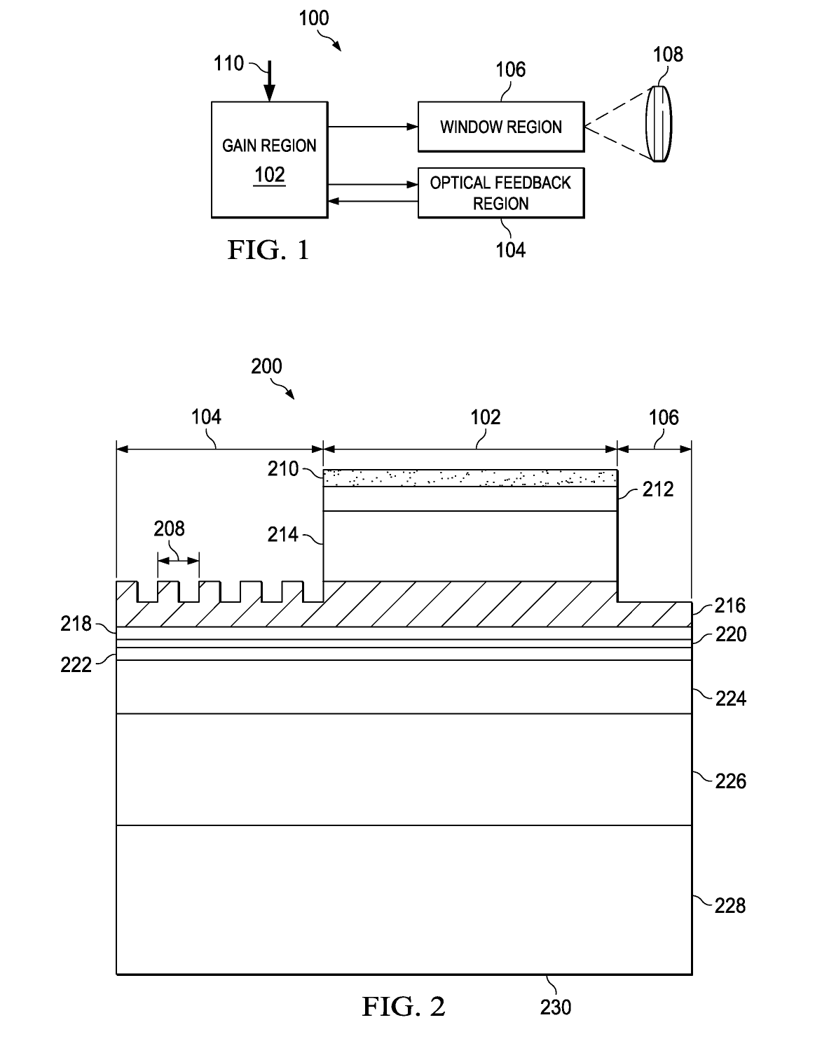

FIG. 1 is a block diagram of a red-shifted optical feedback laser, in accordance with the illustrative embodiments. Laser 100 comprises gain region 102, optical feedback region 104, and window region 106. Gain region 102 is pumped with injected current 110. Optical feedback region 104 and window region 106 are passive or non-pumped regions. Light 108 is emitted from window region 106.

Gain is generally achieved by stimulated emission when there is a high carrier density in the conduction band compared with the valence band (population inversion). Without pumping, most of the electrons in the gain material are in the valence band. Most semiconductor lasers are pumped with an electrical current in a region where an n-doped and a p-doped semiconductor material meet. Pumping excites electrons into a higher state in the conduction band, from where they quickly decay to states near the bottom of the conduction band. At the same time, the holes generated in the valence band move to the top of the valence band. Electrons in the conduction band can then recombine with these holes, emitting photons with an energy near the bandgap energy. This process can also be stimulated by incoming photons with suitable energy.

Lasing mediums may be selected based on the desired emission wavelength. In laser 100, the lasing medium in gain region 102 is pumped, in other words, the lasing medium has current injected 110 to stimulate the carriers into an excited state. Initially, the gain medium absorbs the energy, but after the energy gain is equal to the energy loss, the injected carriers will contribute to the lasing status. As the gain medium saturates, photons in a closely distributed group of wavelengths surrounding a peak wavelength λ_{g} are created. The peak wavelength λ_{g} depends upon the bandgap of the material. In an illustrative embodiment, the gain material λ_{g} is the same for gain region 102 and window region 106 of laser 100. In another embodiment, the gain material profile is the same for gain region 102, optical feedback region 104, and window region 106 of laser 100.

An optical feedback region is a region with a periodic variation of the refractive index, so that a large reflectivity may be reached in some wavelength range around a certain wavelength which fulfills the Bragg condition: 2π/Λ=22πn/λ cos θ, where λ is the vacuum wavelength of light, n is the refractive index, θ is the propagation angle in the medium relative to the direction normal to the grating, and Λ is the grating period. If this condition is met, the Bragg wavelength λ_{B} is reflected. Other wavelengths are only weakly affected by the optical feedback region. Around the Bragg wavelength λ_{B}, a nearly total reflection (around 94%) may be achieved. Due to the wavelength dependence of reflection and transmission, an optical feedback region can serve as an optical filter, thus filtering out wavelengths that are different from λ_{B}.

Window region 106 is the region of laser 100 wherein light 108 is emitted. COD failures may occur in the window region 106 if the carrier density accumulates to a level that can not be supported by the disturbed lattice material in the window region 106. Window region 106 is in particularly susceptible because the material lattice of window region 106 is necessarily disturbed at the edge of window region 106 during the etch or cleaving of window region 106 at formation.

FIG. 2 illustrates exemplary layers of a semiconductor laser for a red-shifted optical feedback DBR laser. Laser 200 comprises gain region 102, optical feedback region 104, and window region 106. Gain region 102 is comprised of layers of materials, which may or may not be epitaxially disposed on a substrate. Gain region 102 in laser 200 may comprise a P metal layer 210. P metal layer 210 provides for a contact for current injection into gain region 102. Highly-doped cap layer 212, which may be comprised of GaAs, for example, is under P metal layer 210, which may in turn be stacked on a highly-doped P-cladding 214, which may be comprised of AlGaAs, for example. The pump current is injected (not shown) into gain region 102 through P metal layer 210 and highly-doped cap layer 212 and highly-doped P cladding 214.

Note that these layers, P metal 210 and highly-doped cap 212, are not included in the optical feedback region 104 or window region 106. Further, highly-doped P cladding 214 is not included intact in the optical feedback region 104 or window region 106. In other words, highly-doped P cladding layer in the passive regions may be thinner than in the regions configured for gain. Optical feedback region 104 and window region 106 are passive regions, meaning that these regions are not configured to be actively pumped with injected current. However, charge carriers may diffuse into these regions from the gain region 102. Further note that layers low doped p cladding 216, P Graded Index Separate Confinement Heterostructure (P GRINSCH) 218, quantum well area 220, N GRINSCH 222, low doped N-cladding 224, high doped N-cladding 226, and N substrate 228 are common to all of gain region 102, window region 106 and, in an illustrative embodiment, optical feedback region 104.

Optical feed back region 104 is a distributed Bragg reflector (DBR) in an embodiment as shown. A DBR may be a reflector that is formed from multiple layers of alternating materials with a varying refractive index, or by periodic variation of some characteristic (such as height) of a dielectric waveguide, resulting in periodic variation in the effective refractive index in the guide. Each layer boundary causes a partial reflection of an optical wave. For waves whose wavelength is close to four times the optical thickness of the layers, the many reflections combine with constructive interference, and the layers act as a high-quality reflector. In this embodiment, gain region 102, window region 106 and optical feedback region 104 have the same λ_{g}, the DBR λ_{B} however is detuned, red-shifted from λ_{g}.

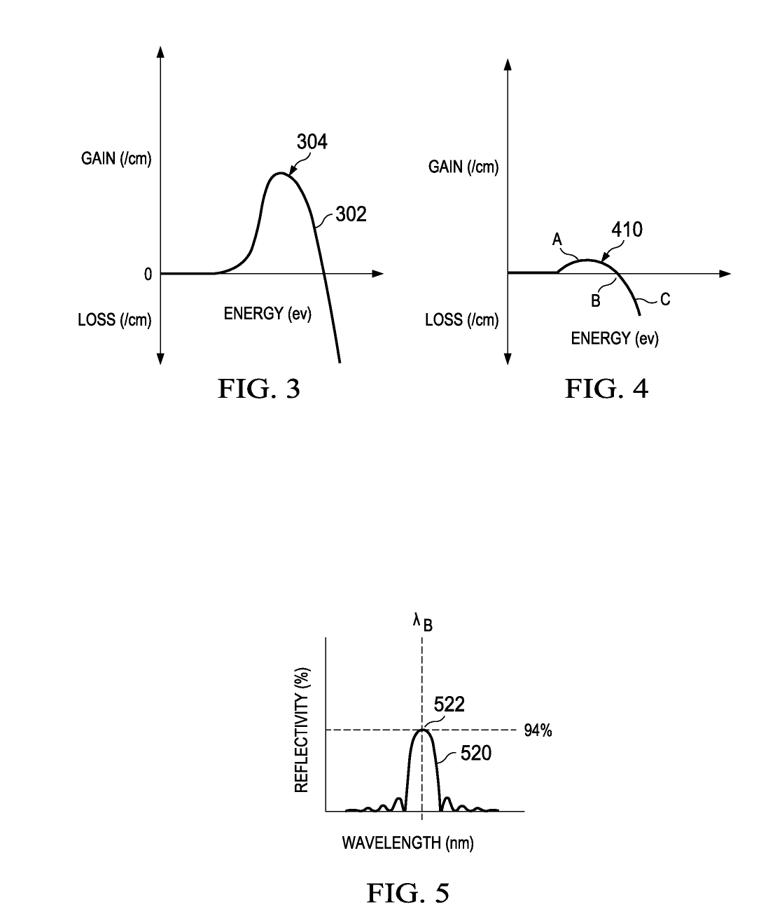

Turning to FIG. 3, a graph of gain/loss (/cm) versus energy (eV) for a gain region, such as gain region 102 of FIG. 1, is shown. Curve 302 illustrates gain/loss versus energy in a gain region. The y-axis indicates gain, in the positive direction, and loss, in the negative direction. The x-axis indicates energy (eV) in the gain region. The energy emitted is in the form of photons (light energy). Recall that (light) energy E is related to wavelength λ as follows: E˜1/λ. The photons emitted have distribution centering on a specific wavelength that depends on the state of the electron's energy when the photon is released. Two identical atoms with electrons in identical states will release photons with identical wavelengths. The peak 304 of curve 302 indicates the highest energy of the gain material, which in turn, indicates the peak wavelength λ_{g} of the gain material in the quantum well.

Turning to FIG. 4, a graph of gain/loss (/cm) versus energy (eV) for a passive area, such window region 106 in FIG. 1 is shown. The passive areas are not injected with current; however, some carriers diffuse into the passive regions, and further the passive regions receive energy in the form of photons from the gain region. Therefore, a passive area initially exhibits gain. The electrons absorb energy from the diffused carriers and photons fill the valance band of the gain material that is in the quantum well of the passive window region. As the valance band fills, electrons then release this energy. As the electrons relax, some energy is released in the form of spontaneous emission photons, heat, and collisions. Most likely, the spontaneous emission photons will be misdirected causing further collisions and heat in the passive area. Therefore, gain/loss curve 410 initially shows gain (see region A), then at increased energies the passive region becomes “lossy,” in other words, the passive regions begin absorbing more energy than transmitting or reflecting (see region C) the energy. At region B, the passive region experiences neither gain nor loss. Therefore, at region B, the passive region is transparent to the specific wavelength related to that specific energy. Since a specific energy relates to a specific wavelength, the passive region is transparent to that specific wavelength.

FIG. 5 is a graph of reflectivity (%) versus wavelength (λ) for an optical feedback region of a semiconductor laser. The reflectivity is indicated on the y-axis and the wavelength is indicated on the x-axis. Curve 520 shows a peak 522 at Bragg wavelength λ_{B}. The Bragg wavelength λ_{B} is determined by the period Λ of the optical feedback grating, such as Λ 208 in FIG. 2. Whether the optical feedback region is internal to the laser such as in a DBR laser, internal to the gain region such as a DFB laser, or external to the laser such as a Fabry-Perot laser with an external grating, it is the period Λ of the grating that determines λ_{B}. As can be seen from curve 520, the optical feedback region is about 94% reflective for the specific wavelength λ_{B} at the designed grating depth.

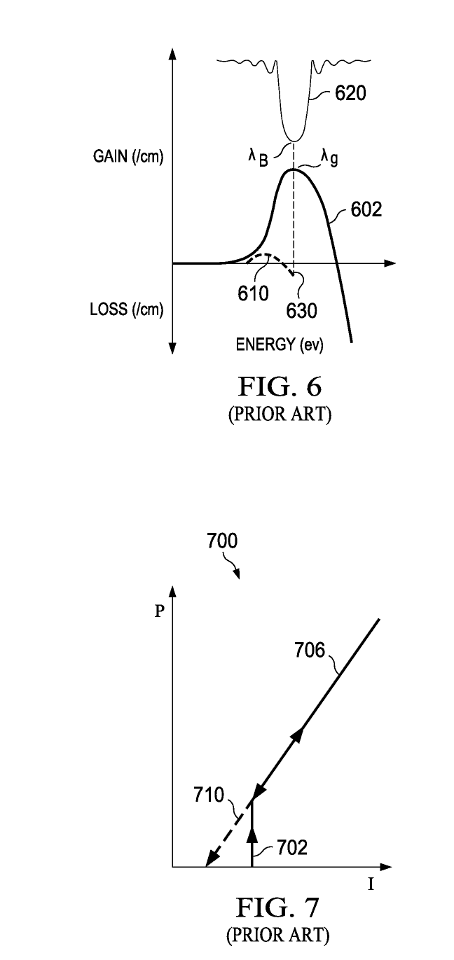

FIG. 6 shows a composite graph illustrating the function of a prior art laser. A gain/loss graph for the gain region, curve 602, and the gain/loss graph for the passive region, curve 610 are overlain with the reflectivity graph of the optical feedback region, curve 620. The prior art laser comprises an optical feedback region with a grating of period Λ_{g} so that the Bragg wavelength λ_{B} of the optical feedback region is substantially equal to λ_{g}. λ_{B} is the wavelength which receives the optical feedback from the laser system, therefore it is at λ_{B} that the laser will lase. Since λ_{B} is substantially equal to λ_{g}, the wavelength with the maximum power of the gain material lases, which, in this case, is λ_{g}. Note, that at λ_{g} the gain/loss graph for the passive region curve 610 is in a loss region of the graph.

The losses of the passive region at this wavelength cause the laser to emit less power. Further, a passive region including a facet absorbs energy. Because of the disturbed lattice of the facet, more energy may be absorbed and the semiconductor junction may become overloaded by exceeding its power density. As the facet area absorbs too much of the provided energy, the facet area may become hot and melt and/or crack, permanently damaging the laser with a COD failure. In addition to COD failures, the prior art laser may have an undesirable bi-stable control of the laser. In other words, the turn on of the emitted light does not behave linearly with respect to the injected current.

Turning to FIG. 7, graph 700 illustrates the bi-stable control of a prior art laser. The y-axis is the power (P) or light intensity, and the x-axis is the injected current (I). As the laser is powered up, an injected current is supplied. Both the gain and passive regions begin to show gain; however, the passive regions, gaining only with diffused carriers, become lossy at higher injected currents. Since more current must be injected to make up for the lossy passive region, the laser does not begin to emit and P remains at zero. The laser then suddenly “snaps on,” as shown in curve 702. Once the lossyness of the passive region is compensated for, the expected linear relationship is exhibited, curve 706. The laser may then have less current injected into it and may be tuned back along linear curve 710.

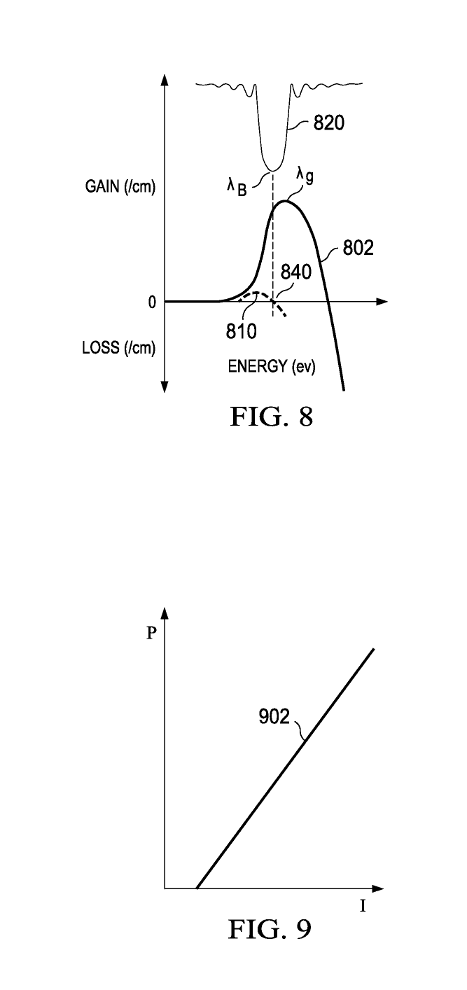

FIG. 8 shows a composite graph illustrating the function of a red-shifted optical feedback laser in accordance with an illustrative embodiment. Curve 802 illustrates the gain/loss versus energy of the gain region of the red-shifted optical feedback laser. Curve 804 shows the gain/loss versus energy of the passive regions of the red-shifted optical feedback laser. Curve 806 shows the reflectivity versus wavelength of the optical feedback region 104. The period Λ of the red-shifted optical feedback laser grating is shifted to a longer wavelength than the λ_{g} of the gain material. Λ_{B} (the Bragg wavelength of the red-shifted optical feedback region) is offset from λ_{g} by between about 2 nm to about 20 nm. Note that λ_{B} corresponds to point 840 at which the passive region is transparent to the lasing wavelength 808. Therefore, the passive region, such as window region 106 in FIG. 1, does not absorb energy in this range. The red-shifted optical feedback laser may produce more power. Further, because the passive window region 106 is transparent to λ_{B}, the passive window region 106 has minimum heating, and therefore, reduced incidences of COD losses occur and the laser may produce more power, including and up to about 10 W or more.

Still further, because the passive window region is transparent to λ_{B}, the red-shifted optical feedback laser has linear control at start-up. FIG. 9 shows a power (P) versus current (I) graph illustrating a linear control of a red-shifted optical feedback laser in accordance with an illustrative embodiment. Because the gain region of the red-shifted optical feedback laser does not need to compensate for the lossy absorption of the passive region, the red-shifted optical feedback laser demonstrates a linear relationship between power and injected current curve 902.

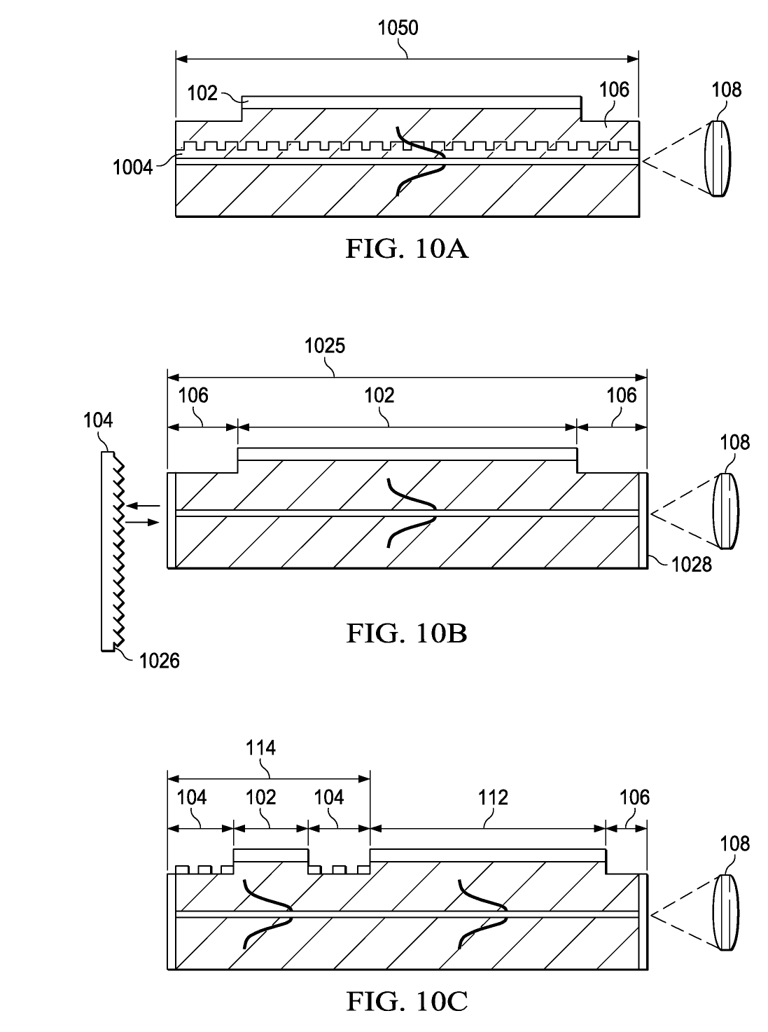

FIGS. 10A-10C are cross-sectional views of three further embodiments of semiconductor lasers with red-shifted optical feedback regions. An embodiment showing a DBR optical feedback system was illustrated in FIG. 2. However, lasers with other types of optical feedback regions are within the scope of the illustrative embodiments, including distributed feedback lasers (DFB) (see FIG. 10A), Fabry-Perot lasers with external gratings (see FIG. 10B), as well as more complex laser systems that include amplifiers, such as master oscillator power amplifier (MOPA) (see FIG. 10C), for example. In all of the optical feedback regions, the lasing wavelength is selected by implementing an optical feedback region with a period Λ and λ_{B}>λ_{g}. In other words, the optical feedback region is red-shifted from the gain region.

Turning to FIG. 10A, a distributed feedback (DFB) red-shifted optical feedback laser is shown. DFB laser 1000 comprises gain region 102, window region 106, and optical feedback region 104 (in this embodiment 1004). The optical feedback region 1004 depicted in distributed feedback laser 1000 is essentially the entire laser cavity 1050, which comprises periodic structure 1004 of period Λ. A distributed feedback laser may be thought of as two Bragg gratings with internal optical gain. Periodic structure 1004 acts as the distributed reflector. The wavelength of periodic structure 1004 is red-shifted from the maximum wavelength of the gain profile (λ_{B}>λ_{g}). Distributed feedback lasers in general are known by those of ordinary skill in the art and therefore will not be discussed in detail herein, except as the optical feedback region in the DFB laser relates to a red-shifted optical feedback region of an illustrative embodiment.

Turning to FIG. 10B, another illustrative embodiment, a Fabry-Perot laser with an external red-shifted optical feedback region 104 is shown. Fabry-Perot laser 1025 comprises gain region 102, window regions 106, and an external optical feedback region 104. External optical feedback may not be comprised of the same gain material as gain region 102 and window region 106. A Fabry-Perot laser 1025 may employ a fiber Bragg grating 1026 as optical feedback region 104.

A fiber Bragg grating may be a periodic perturbation of the effective refractive index in the core of an optical fiber 1026. Typically, the perturbation is approximately periodic over a certain length, for example, a few millimeters or centimeters, and the period is of the order of hundreds of nanometers. The fiber Bragg grating may be, for example, a meter long with one or more periodic perturbation regions within. The reflection of light propagating along the fiber is in a narrow range of wavelengths, for which a Bragg condition is satisfied. The complex amplitudes corresponding to reflected field contributions from different parts of the grating are all in phase, so that they can add up constructively. Other wavelengths are minimally affected by the fiber Bragg grating. Therefore, the fiber Bragg grating, as other optical feedback region in these embodiments, determines the lasing wavelength of the laser system.

For example, Fabry-Perot laser 1025 plus fiber Bragg grating 1026 is a laser oscillator in which two mirrors 1026 and 1028 are separated by the laser medium in gain region 102. A first mirror 1028 is a highly reflecting mirror that reflects light through gain region 102. Fiber Bragg grating 1026 is the other reflective structure that forms a standing light wave allowing gain region 102 to lase. A Fabry-Perot laser is not, in itself, a frequency selective configuration. However, Fabry-Perot laser in combination with optical feedback region 104, such as a FBG 1026, is a frequency selective configuration. The λ_{B} of 1026 is red-shifted from λ_{g} of gain region 102. Further, window regions 106 are transparent to λ_{B}.

Turning to FIG. 10C, a master oscillator power amplifier (MOPA) is a laser system consisting of a master laser 114 (or seed laser) and an optical amplifier 112 to boost the output power. The frequency stabilized semiconductor master laser 114 provides the “template” frequency and phase so that the output of the fiber amplifier is the amplified (higher watt) frequency and phase of the frequency stabilized semiconductor seed laser 114. In this embodiment, gain region 102 and optical feedback regions 106 are separated from window region 106 by amplifier region 112.

In each of these illustrative embodiments, the gain region and the window region have a quantum well structure of similar materials.

Advantages of embodiments include providing an infrared range laser wherein a greater power may be achieved, fewer or no COD failures may occur and the laser has a linear control at start up.

Although the illustrative embodiment and its advantages have been described in detail, it should be understood that various changes, substitutions, and alterations can be made herein without departing from the spirit and scope of the invention as defined by the appended claims. For example, it will be readily understood by those skilled in the art that currents and wavelengths may be varied while remaining within the scope of the present invention.

Moreover, the scope of the present application is not intended to be limited to the particular embodiments of the process, machine, manufacture, composition of matter, means, methods, and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor laser comprising:
a quantum well layer with a peak wavelength λg;
a laser gain region configured to accept a current injected into the quantum well layer;
a window region that includes a light-emitting facet, wherein the window region is configured to be passive; and
an optical feedback region with a Bragg wavelength λB, and wherein λB>λg.

2. The semiconductor laser of claim 1, wherein the quantum well layer is uniform across the gain region and the window region.

3. The semiconductor laser of claim 1, wherein λB is between about 2 and about 20 nm greater than λg.

4. The semiconductor laser of claim 1, wherein a peak wavelength of a light emitted from the light emitting facet is comprised substantially of λB.

5. The semiconductor laser of claim 1, wherein a light emitted by the light-emitting facet is greater than 5 W.

6. The semiconductor laser of claim 1, wherein the optical feedback region is a distributed Bragg reflector (DBR).

7. The semiconductor laser of claim 1, wherein the optical feedback region is distributed feedback (DFB).

8. The semiconductor laser of claim 1, wherein the optical feedback region is external to the quantum well layer.

9. The semiconductor laser of claim 1, wherein an amplifier is between the optical feedback region and the window region.

10. A method of producing 600-1100 nm laser light, the method comprising:
injecting current into a quantum well layer of a gain region, wherein the quantum well layer has a peak wavelength of λg;
providing optical feedback at a peak wavelength of λB, wherein λB is greater than λg; and
emitting light through a window region comprising the quantum well layer and a facet, wherein the facet emits light at a peak wavelength of λB.

11. The method of claim 10, wherein the light is emitted at a power of greater than 5 W.

12. The method of claim 10, wherein the light emitted is substantially transparent to the window region.

13. The method of claim 10 further comprising:
emitting light essentially in a linear relationship to the injecting current.

14. The method of claim 10, wherein λB is greater than λg by about 2 to about 20 nm.

15. A method of making a laser diode, the method comprising:
providing a quantum well layer that has a peak wavelength λg;
providing a laser gain region;
providing a window region that includes a light-emitting facet, wherein the window region is configured to be passive; and
providing an optical feedback region, wherein the optical feedback region has a Bragg wavelength λB, and wherein λB>λg.

16. The method of claim 15, wherein a peak wavelength of a light emitted from the light emitting facet is comprised substantially of λB.

17. The method of claim 15, wherein a laser light output from the light-emitting facet is greater than 5 W.

18. The method of claim 15 further comprising:
providing a uniform quantum well layer across the laser gain region and the window region.

19. The method of claim 15, wherein the window region is effectively transparent to the emitted light.

20. The method of claim 15, wherein λB is greater than λg by about 2 nm to about 20 nm.
